(19) United States
(12) Patent Application Publication
(10) Pub. No.: US 2024/0324415 A1
(43) Pub. Date: Sep. 26, 2024

(54) DISPLAY APPARATUS

(71) Applicant: Samsung Display Co., Ltd., Yongin-si (KR)

(72) Inventor: Joonyung Jang, Yongin-si (KR)

(73) Assignee: Samsung Display Co., Ltd., Yongin-si (KR)

(21) Appl. No.: 18/539,582

(22) Filed: Dec. 14, 2023

(30) Foreign Application Priority Data
Mar. 24, 2023 (KR) 10-2023-0039164
May 23, 2023 (KR) 10-2023-0066481

(51) Int. Cl. H10K 59/80

(52) U.S. Cl. CPC H10K 59/878; H10K 59/873; H10K 59/8792

(57) ABSTRACT

A display apparatus includes a display element layer on a substrate, a cover window on the display element layer, and a light control film between the display element layer and the cover window. The light control film includes a reflective wall structure including reflective particles, and a light-transmissive layer covering a sidewall of the reflective wall structure. A width of a lower surface of the reflective wall structure is less than a width of an upper surface of the reflective wall structure, and the lower surface of the reflective wall structure faces the display element layer.

### CROSS-REFERENCE TO RELATED APPLICATIONS

This application claims priority to and benefits of Korean Patent Application Nos. 10-2023-0039164, filed on Mar. 24, 2023, and 10-2023-0066481, filed on May 23, 2023, under 35 U.S.C. § 119, in the Korean Intellectual Property Office, the entire contents of which are incorporated herein by reference.

### BACKGROUND

### 1. Field

Embodiments relate to a display apparatus and a method of manufacturing the same.

### 2. Description of the Related Art

Recently, display apparatuses have been widely used. Also, because the thickness and weight of the display apparatuses have been decreased, the use of the display apparatuses has widened. As display apparatuses have been used in various fields, there is an increasing demand for display apparatuses capable of providing high-quality images.

### SUMMARY

Embodiments include a display apparatus with limited viewing angle characteristics. However, the scope of the disclosure is not limited thereto.

Additional aspects will be set forth in part in the description which follows and, in part, will be apparent from the description, or may be learned by practice of the presented embodiments of the disclosure.

According to an embodiment, a display apparatus may include a display element layer on a substrate, a cover window on the display element layer, and a light control film between the display element layer and the cover window. The light control film may include a reflective wall structure including a plurality of reflective particles, and a light-transmissive layer covering a sidewall of the reflective wall structure. A width of a lower surface of the reflective wall structure may be less than a width of an upper surface of the reflective wall structure, and the lower surface of the reflective wall structure may face the display element layer.

The reflective wall structure may further include a first reflective wall structure and a second reflective wall structure provided on the first reflective wall structure.

A width of a lower surface of the first reflective wall structure may be less than a width of an upper surface of the first reflective wall structure, and a width of a lower surface of the second reflective wall structure may be less than a width of an upper surface of the second reflective wall structure.

The reflective wall structure may further include a third reflective wall structure provided on the second reflective wall structure.

The reflective wall structure may further include a base layer, the plurality of reflective particles may be provided in the base layer, and a refractive index of the base layer may be in a range of about 90% to about 110% of a refractive index of the light-transmissive layer.

Each of the plurality of reflective particles may include a bead portion and a reflection shell portion covering the bead portion.

The bead portion may be completely covered by the reflection shell portion.

The reflection shell portion may cover a portion of the bead portion, and another portion of the bead portion may be exposed by the reflection shell portion. The bead portion may have a circular cross-sectional shape.

The bead portion may have an oval cross-sectional shape.

The bead portion may include a transmissive polymer, and the reflection shell portion may include a metal or a metal oxide.

The light control film may further include a first organic layer on the lower surface of the reflective wall structure and a lower surface of the light-transmissive layer, and a second organic layer on the upper surface of the reflective wall structure and an upper surface of the light-transmissive layer, the first organic layer may include a first transparent polymer, and the second organic layer may include a second transparent polymer.

The display apparatus may further include an encapsulation layer between the display element layer and the light control film, and an anti-reflection layer between the encapsulation layer and the light control film.

The display apparatus may further include a lower adhesive layer between the display element layer and the light control film, and an upper adhesive layer between the light control film and the cover window.

According to an embodiment, a display apparatus may include a display element layer on a substrate, a light control film on the display element layer, and a cover window on the light control film. The light control film may include a plurality of reflective wall structures spaced apart from each other, and a light-transmissive layer between the plurality of reflective wall structures, and each of the plurality of reflective wall structures may include a first reflective wall structure including a first base layer and a plurality of first reflective particles, and a second reflective wall structure provided on an upper surface of the first reflective wall structure and including a second base layer and a plurality of second reflective particles.

An angle between the lower surface and a sidewall of the first reflective wall structure may be an obtuse angle, and an angle between the lower surface and a sidewall of the second reflective wall structure may be an obtuse angle.

A width of the lower surface of the second reflective wall structure may be less than a width of the upper surface of the first reflective wall structure.

The light-transmissive layer may include a first light-transmissive layer covering a sidewall of the first reflective wall structure, and a second light-transmissive layer disposed above the first light-transmissive layer and covering a sidewall of the second reflective wall structure.

The second light-transmissive layer may cover a portion of the upper surface of the first reflective wall structure.

The second light-transmissive layer and the first light-transmissive layer may include a same material.

Other aspects, features, and advantages other than those described above will become apparent from the following detailed description, claims and drawings for carrying out the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a schematic cross-sectional view of the display apparatus of FIG. 1, taken along line A-A′ of FIG. 1;

FIG. 3 is a schematic diagram of an equivalent circuit of a pixel according to an embodiment;

FIG. 4 is a schematic plan view of a display apparatus according to an embodiment;

FIG. 5 is an enlarged plan view showing region B of the display apparatus of FIG. 4;

FIG. 6 is a schematic cross-sectional view of the display apparatus of FIG. 5, taken along line C-C′ of FIG. 5;

FIG. 7 is an enlarged view showing region D of FIG. 6;

FIG. 8A is a schematic diagram for explaining a first sub-reflective particle according to an embodiment;

FIG. 8B is a schematic diagram for explaining a second sub-reflective particle according to an embodiment;

FIG. 8C is a schematic diagram for explaining a third sub-reflective particle according to an embodiment;

FIG. 8D is a schematic diagram for explaining a fourth sub-reflective particle according to an embodiment;

FIG. 9A is a schematic diagram for explaining a reflective wall structure according to another embodiment and an enlarged view of region DD of FIG. 7;

FIG. 9B is a schematic diagram for explaining a reflective wall structure according to another embodiment;

FIG. 10A is a schematic diagram for explaining a light control film according to an embodiment and corresponds to an enlarged view of region E of FIG. 7;

FIG. 10B is a schematic diagram for explaining a light control film according to another embodiment;

FIG. 10C is a schematic diagram for explaining a light control film according to another embodiment;

FIG. 11 is a schematic diagram for explaining a light control film according to another embodiment;

FIGS. 12A to 12E are schematic diagrams for explaining manufacture of a light control film, according to embodiments; and

FIGS. 13A to 13E are schematic diagrams for explaining manufacture of a light control film, according to embodiments.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, particular embodiments will be shown in the drawings and described in detail in the written description. The attached drawings for illustrating embodiments of the disclosure are referred to in order to gain a sufficient understanding of the disclosure, the merits thereof, and the objectives accomplished by the implementation of the disclosure. The disclosure may, however, be embodied in many different forms and should not be construed as being limited to the embodiments set forth herein.

Hereinafter, embodiments will be described in detail with reference to the accompanying drawings. Like elements in the drawings denote like elements, and repeated descriptions thereof are omitted.

It will be understood that although the terms “first,” “second,” etc. may be used herein to describe various elements, these elements should not be limited by these terms, and these elements are only used to distinguish one element from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or elements, but do not preclude the presence or addition of other features or elements.

It will be understood that when a layer, region, or element is referred to as being “formed on” another layer, region, or element, it can be directly or indirectly formed on the other layer, region, or element. That is, for example, intervening layers, regions, or elements may be present.

It will be understood that when a layer, region, or component is referred to as being connected to another layer, region, or component, it can be directly or indirectly connected to the other layer, region, or component. For example, when a layer, region, or component is referred to as being electrically connected to another layer, region, or component, it can be directly or indirectly electrically connected to the other layer, region, or component.

In the embodiment, an expression such as “A and/or B” indicates A, B, or A and B. Also, an expression such as “at least one of A and B” indicates A, B, or A and B.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the specification, the term “about” or “approximately” used to refer to an arbitrary number may indicate figures within a range that is generally accepted in the relevant art due to measurement limits or errors. For example, the term “about” may indicate values in a range of +30%, 20%, 10%, or 5%.

When a certain embodiment may be implemented differently, a specific process order may be performed differently from the described order. For example, two consecutively described processes may be performed substantially at the same time or performed in an order opposite to the described order.

Sizes of elements in the drawings may be exaggerated for convenience of explanation. In other words, since sizes and thicknesses of elements in the drawings are arbitrarily illustrated for convenience of explanation, the following embodiments are not limited thereto.

Throughout the specification, like reference numerals and like reference symbols denote like elements.

Hereinafter, a display apparatus and a method of manufacturing the same according to embodiments are described.

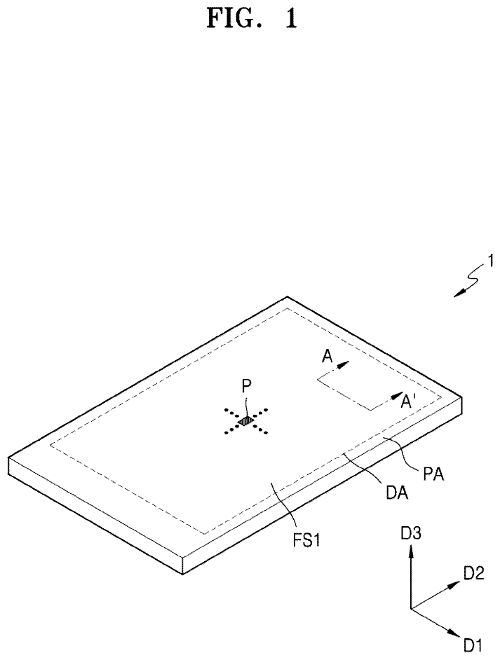

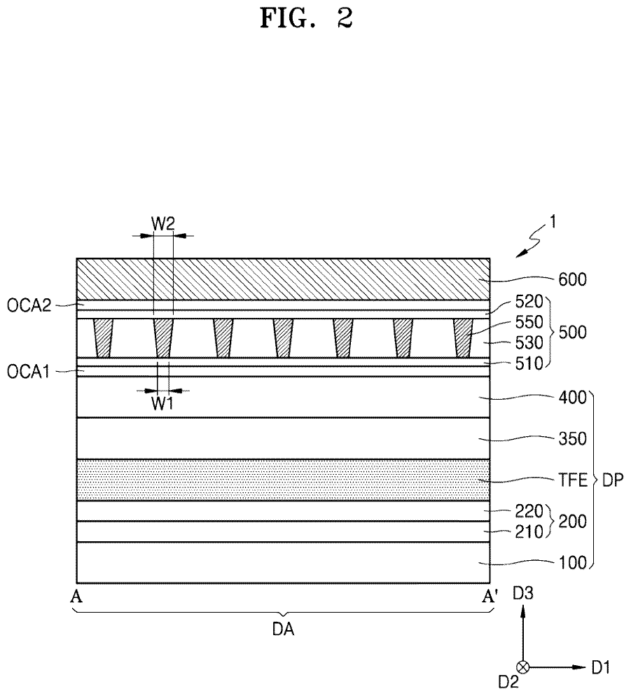

FIG. 1 is a schematic perspective view of a display apparatus according to an embodiment. FIG. 2 is a schematic cross-sectional view of the display apparatus of FIG. 1, taken along line A-A′ of FIG. 1.

Referring to FIG. 1, a display apparatus 1 according to an embodiment may include a display area DA and a peripheral area PA. The peripheral area PA may be disposed adjacent (or surround) the display area DA. In the peripheral area PA, various lines configured to transmit electrical signals to be applied to the display area DA and driving circuitry may be located. The display apparatus 1 may provide image by using light emitted from multiple pixels arranged in the display area DA.

Hereinafter, an organic light-emitting display apparatus is described as an embodiment of the display apparatus 1, but the disclosure is not limited thereto. The display apparatus 1 may be a display apparatus, such as an organic light-emitting display apparatus, an inorganic light-emitting display apparatus (or an inorganic EL display apparatus), or a quantum dot light-emitting display apparatus.

The display apparatus 1 may be realized as various types of electronic apparatuses. In an embodiment, the display apparatus 1 may be for a vehicle, but the disclosure is not limited thereto.

As shown in FIG. 2, the display apparatus 1 may include a display panel DP, a light control film 500, and a cover window 600. The display panel DP may include a substrate 100, a pixel layer 200, an encapsulation layer TFE, a touch sensor layer 350, and an anti-reflection layer 400.

The substrate 100 may include a glass material or a polymer resin. For example, the substrate 100 may include a glass material, of which the main component is silicon oxide (SiO_{X}), or a polymer resin including polyethersulfone, polyarylate, polyetherimide, polyethylene naphthalate, polyethylene terephthalate (PET), polyphenylene sulfide, polyimide (PI), polycarbonate (PC), cellulose triacetate, and/or cellulose acetate propionate.

A pixel layer 200 may be disposed above the substrate 100. The pixel layer 200 may include a pixel circuit layer 210 and a display element layer 220. The display element layer 220 may include a display element. The pixel circuit layer 210 may include a pixel circuit and insulating layers. The display element may include an organic light-emitting diode or an inorganic light-emitting diode. The display element layer 220 may be disposed above the pixel circuit layer 210, and the insulating layers may be arranged between the pixel circuit and the display element. Some lines and the insulating layers of the pixel circuit layer 210 may extend to the peripheral area PA.

The encapsulation layer TFE may be disposed above the pixel layer 200. The encapsulation layer TFE may seal the display element in the display element layer 220. In an embodiment, the encapsulation layer TFE may include at least one inorganic encapsulation layer and at least one organic encapsulation layer.

The touch sensor layer 350 may be disposed above the encapsulation layer TFE. The touch sensor layer 350 may sense a touch input from a user. The touch sensor layer 350 may sense a touch input from the user in a resistive manner or a capacitive manner. FIG. 2 shows that the touch sensor layer 350 is disposed above the encapsulation layer TFE, but the touch sensor layer 350 may be disposed above the pixel layer 200 or formed in the encapsulation layer TFE.

The anti-reflection layer 400 may be disposed above the touch sensor layer 350. The anti-reflection layer 400 may reduce the reflectivity of light (external light) that is incident towards the display apparatus 1 from the outside. The anti-reflection layer 400 may include a retarder and a polarizer. The retarder may be of a film type or a liquid crystal coating type and may include a λ/2 retarder and/or a λ/4 retarder.

The polarizer may be of a film type or a liquid crystal coating type. The retarder/polarizer of a film type may include a stretched synthetic resin film, while the retarder/polarizer of a liquid crystal coating type may include liquid crystals arranged in a specific configuration. The anti-reflection layer 400 may further include a protective film.

Although not shown, the display apparatus 1 may further include an optically clear adhesive layer on a lower surface of the anti-reflection layer 400. The optically clear adhesive layer may attach the anti-reflection layer 400 to the touch sensor layer 350.

The cover window 600 may be disposed above the display panel DP. The cover window 600 may be transparent. The cover window 600 may protect the display panel DP. The cover window 600 may include at least one of glass, sapphire, and plastic. The cover window 600 may include, for example, ultra-thin glass (UTG) or colorless polyimide (CPI).

The light control film 500 may be arranged between the display panel DP and the cover window 600. For example, the light control film 500 may be arranged between the pixel layer 200 and the cover window 600. For example, the light control film 500 may be arranged between the anti-reflection layer 400 and the cover window 600.

The light control film 500 may include multiple reflective wall structures 550 and a light-transmissive layer 530. The reflective wall structures 550 may be arranged apart from each other. A width W2 of an upper surface of each reflective wall structure 550 may be greater than a width W1 of a lower surface of the reflective wall structure 550. The light-transmissive layer 530 may be provided between the reflective wall structures 550. Light emitted from the pixel layer 200 may be discharged to the outside through the light-transmissive layer 530.

The light control film 500 may at least partially block external or internal reflection light to limit the viewing angle of light emitted from the display element layer 220. For example, the light control film 500 may transmit light emitted perpendicular to the front surface FS1 of the display apparatus 1 and may block light that is emitted at an angle formed with the front surface FS1 of the display apparatus 1, the angle being less than or equal to a certain angle. Hereinafter, in the specification, first light may refer to light emitted perpendicular to the front surface FS1 of the display apparatus 1, and second light may refer to light emitted at an angle formed with the front surface FS1 of the display apparatus 1, the angle being less than or equal to a certain angle. For example, the second light emitted from the display element layer 220 may be incident to the reflective wall structures 550 at a certain angle. With the presence of the reflective wall structures 550, it may be difficult for the second light to pass through the light control film 500. The first light emitted from the display element layer 220 may be externally discharged through the light-transmissive layer 530.

The light control film 500 may further include a first organic layer 510 and a second organic layer 520. The first organic layer 510 may be provided on lower surfaces of the reflective wall structures 550 and a lower surface of the light-transmissive layer 530. For example, the first organic layer 510 may be provided between the reflective wall structures 550 and the display panel DP and between the light-transmissive layer 530 and the display panel DP. The first organic layer 510 may be transparent. The first organic layer 510 may include a polymer.

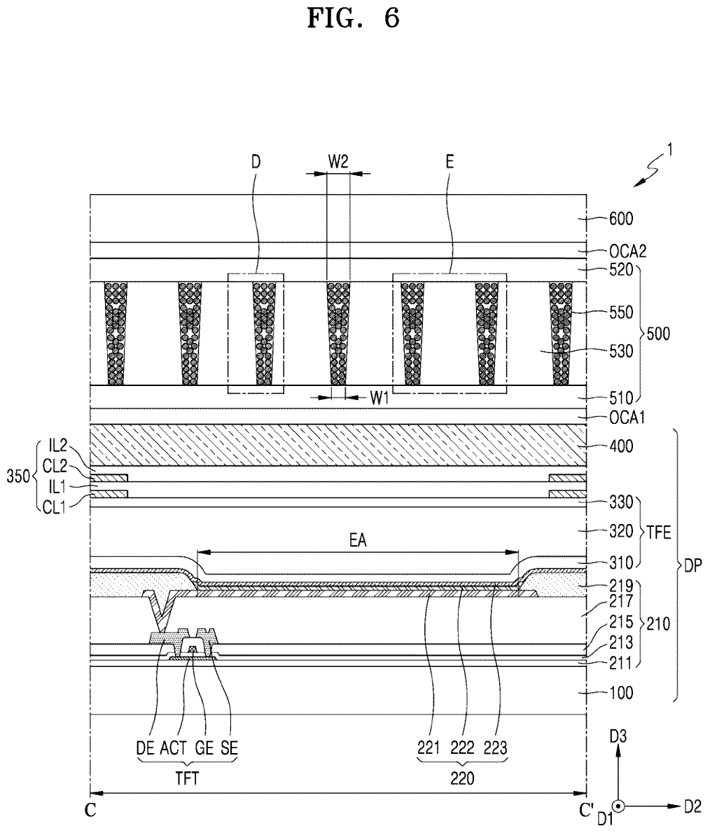

The second organic layer 520 may be provided on the upper surfaces of the reflective wall structures 550 and the upper surface of the light-transmissive layer 530. The second organic layer 520 may be transparent. The second organic layer 520 may include a polymer. In another embodiment, the light control film 500 may not include at least one of the second organic layer 520 and the first organic layer 510. The light control film 500 is described below in more detail with reference to FIGS. 6 to 11.

The display apparatus 1 may further include a lower adhesive layer OCA1. The lower adhesive layer OCA1 may be provided between the anti-reflection layer 400 and the light control film 500. The light control film 500 may be attached to the anti-reflection layer 400 by the lower adhesive layer OCA1. The lower adhesive layer OCA1 may be an optically clear adhesive, but is not limited thereto.

The display apparatus 1 may further include an upper adhesive layer OCA2. The upper adhesive layer OCA2 may be arranged between the light control film 500 and the cover window 600. The cover window 600 may be attached to the light control film 500 by the upper adhesive layer OCA2. The upper adhesive layer OCA2 may be an optically clear adhesive, but is not limited thereto.

In another embodiment, at least one of the encapsulation layer TFE, the touch sensor layer 350, the anti-reflection layer 400, the lower adhesive layer OCA1, and the upper adhesive layer OCA2 may be omitted.

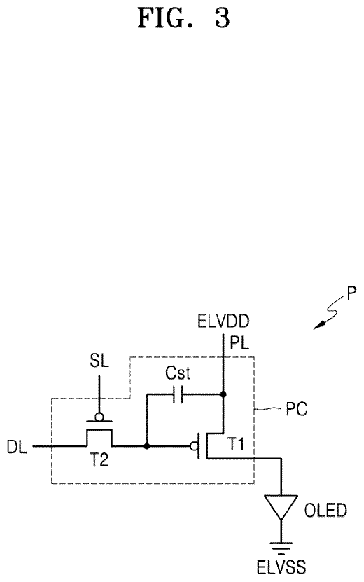

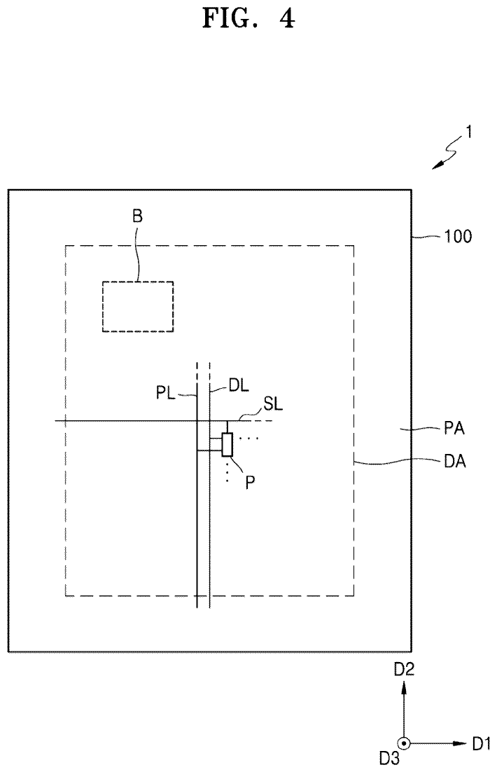

FIG. 3 is a schematic diagram of an equivalent circuit of a pixel according to an embodiment. FIG. 4 is a schematic plan view of a display apparatus according to an embodiment.

Referring to FIGS. 3 and 4, the substrate 100 of the display apparatus 1 may be divided into the display area DA and the peripheral area PA. The display apparatus 1 may provide certain images by using light emitted from pixels P arranged in the display area DA.

Each pixel P may include a display element, such as an organic light-emitting diode OLED or an inorganic light-emitting diode, and may emit, for example, red light, green light, blue light, or white light. For example, as shown in FIG. 3, each pixel P may be connected to a pixel circuit PC including a thin-film transistor TFT, a storage capacitor Cst, and the like. Such a pixel circuit PC may be connected to a scan line SL, a data line DL intersecting the scan line SL, and a driving power line PL. In an embodiment, the scan line SL may extend in a first direction D1, and the data line DL and the driving power line PL may extend in a second direction D2. The second direction D2 may intersect the first direction D1. A third direction D3 may intersect the first direction D1 and the second direction D2. For example, the first direction D1 may be an x-axis direction, the second direction D2 may be a y-axis direction, and the third direction may be a z-axis direction, but the disclosure is not limited thereto.

While the pixel circuit PC is driven, each pixel P may emit light, and in the display area DA, certain images may be provided using the light emitted from the pixels P. In the specification, the pixel P may be defined as an emission area where one of red light, green light, blue light, and white light is emitted, as described above.

Referring to FIG. 4, the peripheral area PA may be an area where no pixels P are arranged, and images may not be provided therein. In the peripheral area PA, embedded driving circuitry for driving the pixels P, power supply lines, a terminal connected to a printed circuit board or a driver IC including driving circuitry, and the like may be arranged.

In each pixel P, the display element (e.g., the organic light-emitting diode OLED) may be connected to the pixel circuit PC. As shown in FIG. 3, the pixel circuit PC may include a first thin-film transistor T1, a second thin-film transistor T2, and the storage capacitor Cst. The organic light-emitting diode OLED may emit, for example, red light, green light, or blue light or emit red light, green light, blue light, or white light.

The second thin-film transistor T2 may be a switching thin-film transistor and connected to the scan line SL and the data line DL. The second thin-film transistor T2 may be configured to transmit, to the first thin-film transistor T1, a data voltage that is input through the data line DL, according to a switching voltage that is input through the scan line SL.

For example, the first thin-film transistor T1 and the second thin-film transistor T2 may each be an n-channel MOSFET (NMOS). In another embodiment, the first thin-film transistor T1 and the second thin-film transistor T2 may each be a p-channel MOSFET (PMOS). In another embodiment, one of the first thin-film transistor T1 and the second thin-film transistor T2 may be an NMOS, and another one of the first thin- film transistor T1 and the second thin-film transistor T2 may be a PMOS.

The storage capacitor Cst may be connected to the second thin-film transistor T2 and the driving power line PL. The storage capacitor Cst may store a voltage corresponding to a difference between a voltage transmitted from the second thin-film transistor T2 and a first power voltage ELVDD provided from the driving power line PL.

The first thin-film transistor T1 may be a driving thin-film transistor and connected to the driving power line PL and the storage capacitor Cst. The first thin-film transistor T1 may control a driving current flowing to the organic light-emitting diode OLED from the driving power line PL, according to the voltage stored in the storage capacitor Cst. The organic light-emitting diode OLED may emit light having a certain brightness in response to the driving current. An opposite electrode (e.g., a cathode) of the organic light-emitting diode OLED may receive a second power voltage ELVSS.

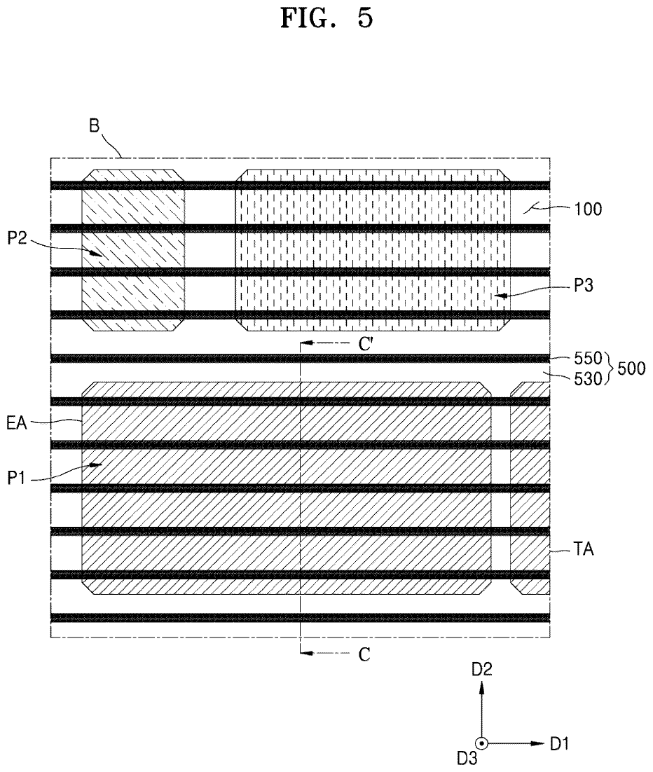

FIG. 3 shows that the pixel circuit PC includes two thin-film transistors T1 and T2 and one storage capacitor Cst, but the disclosure is not limited thereto. The number of thin-film transistors and the number of storage capacitors may vary. FIG. 5 is an enlarged plan view of region B of the display apparatus of FIG. 4.

Referring to FIG. 5, a first pixel P1, a second pixel P2, and a third pixel P3 may be disposed above the substrate 100. The pixels P of FIGS. 1 to 4 may include the first pixel P1, the second pixel P2, and the third pixel P3 of FIG. 5. The first pixel P1, the second pixel P2, and the third pixel P3 of FIG. 5 may be defined by emission areas of display elements corresponding to the first pixel P1, the second pixel P2, and the third pixel P3.

The first pixel P1 may emit light in a first wavelength band. For example, the first pixel P1 may emit light in a wavelength band in a range of about 450 nm to about 495 nm. The second pixel P2 may emit light in a second wavelength band. The second wavelength band and the first wavelength band may be different. For example, the second pixel P2 may emit light in a wavelength band in a range of about 630 nm to about 780 nm. The third pixel P3 may emit light in a third wavelength band. The third wavelength band, the first wavelength band, and the second wavelength band may be different. For example, the third pixel P3 may emit light in a wavelength band in a range of about 495 nm to about 570 nm.

The first pixel P1, the second pixel P2, and the third pixel P3 may each have a rectangular shape among polygonal shapes or a shape deformed from the rectangular shape in a plan view. In the specification, the shape modified from the polygonal shape may include a polygon with rounded vertices, and the shape deformed from the rectangular shape may include a rectangle with rounded vertices. For example, the shape of each of the first pixel P1, the second pixel P2, and the third pixel P3 may be a rectangle with rounded vertices in a plan view. In another embodiment, the shape of each of the first pixel P1, the second pixel P2, and the third pixel P3 may be a circle or an oval.

Sizes of the first pixel P1, the second pixel P2, and the third pixel P3 may be different from each other. For example, a planar area of the second pixel P2 may be less than planar areas of the first pixel P1 and the third pixel P3. The planar area of the first pixel P1 may be greater than that of the third pixel P3. However, the disclosure is not limited thereto. For example, the sizes of the first pixel P1, the second pixel P2, and the third pixel P3 may be substantially the same.

The first pixel P1 may be provided in plural, and the first pixels P1 may be arranged apart from each other in the first direction D1. The second pixel P2 may be provided in plural, and the second pixels P2 may be arranged apart from each other in the first direction D1. The first pixels P1 arranged in the first direction D1 may form a first pixel row. The third pixel P3 may be provided in plural, and the third pixels P3 may be arranged apart from each other in the first direction D1. The third pixels P3 and the second pixels P2 may be arranged alternately in the first direction D1. For example, the second pixels P2 may be arranged between the third pixels P3. The second pixels P2 and the third pixels P3 may form a second pixel row arranged in the first direction D1. The second pixel row and the first pixel row may be apart from each other in the second direction D2 or a direction opposite to the second direction D2. The first pixel row and the second pixel row may each be provided in plural, and the first pixel rows may be arranged between the second pixel rows. However, the plane arrangements of the first pixels P1, the second pixels P2, and the third pixels P3 are not limited thereto and may vary. The first pixels P1, the second pixels P2, and the third pixels P3 may be arranged in various forms, such as a PenTile™ structure, a stripe structure, a mosaic structure, or a delta structure. Hereinafter, for convenience of explanation, a single first pixel P1, a single second pixel P2, and a single third pixel P3 are described.

The light control film 500 may be provided on the substrate 100. The light control film 500 may include multiple reflective wall structures 550 and a light-transmissive layer 530. In a plan view, each reflective wall structure 550 may extend in the first direction D1 and overlap the first pixel P1, the second pixel P2, and the third pixel P3. The reflective wall structures 550 may be spaced apart from each other in the second direction D2. The reflective wall structures 550 may reflect light emitted from the first pixel P1, the second pixel P2, and the third pixel P3. The light-transmissive layer 530 may be provided between the reflective wall structures 550. The light-transmissive layer 530 may include multiple light-transmissive layers 530, and the light-transmissive layers 530 may be arranged apart from each other in the second direction D2. Each of the first pixel P1, the second pixel P2, and the third pixel P3 may overlap the reflective wall structures 550, and each light-transmissive layer 530 may overlap multiple light-transmissive portions.

The reflective wall structures 550 may limit light emitted in a specific direction from among the light emitted from the first pixel P1, the second pixel P2, and the third pixel P3. For example, in case that a second direction component of the light emitted from the first pixel P1, the second pixel P2, and the third pixel P3 is greater than a certain value and has an exit angle equal to or greater than a cut-off angle, the emitted light may be blocked by the reflective wall structures 550.

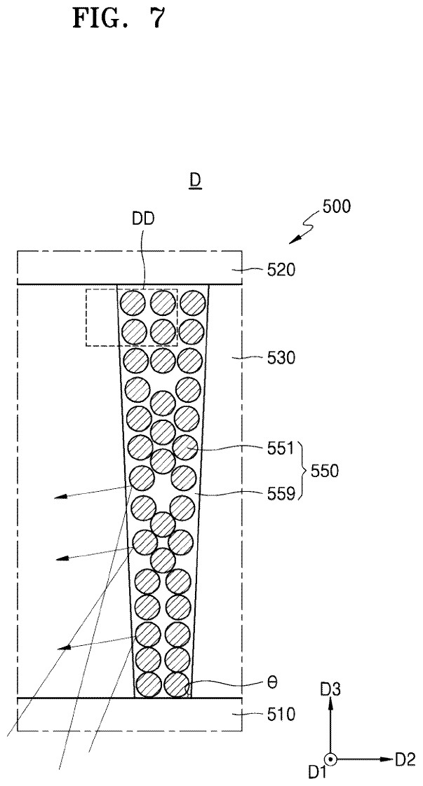

FIG. 6 is a schematic cross-sectional view of the display apparatus of FIG. 5, taken along line C-C′ of FIG. 5. FIG. 7 is an enlarged view of region D of FIG. 6. Hereinafter, the descriptions that are the same as those provided above are omitted.

Referring to FIGS. 6 and 7, the display apparatus 1 according to an embodiment may include the substrate 100, the pixel layer 200, the encapsulation layer TFE, the touch sensor layer 350, the anti-reflection layer 400, the lower adhesive layer OCA1, the light control film 500, the upper adhesive layer OCA2, and the cover window 600. As described above, the substrate 100 may include a glass material or a polymer resin.

The pixel circuit layer 210 may be disposed above the substrate 100. The pixel circuit layer 210 includes the thin-film transistor TFT and a storage capacitor (not shown). The thin-film transistor TFT may include a semiconductor layer ACT, a gate electrode GE, a source electrode SE, and a drain electrode DE. The semiconductor layer ACT may include amorphous silicon, polycrystalline silicon, or an organic semiconductor material. A gate insulating layer 213 may be arranged between the semiconductor layer ACT and the gate electrode GE. The gate insulating layer 213 may secure insulation between the semiconductor layer ACT and the gate electrode GE. The gate insulating layer 213 may include an inorganic material, such as SiOₓ, silicon nitride (SiNₓ), and/or silicon oxynitride (SiON). The gate insulating layer 213 may be formed through Chemical Vapor Deposition (CVD) or Atomic Layer Deposition (ALD).

An interlayer insulating layer 215 may be disposed above the gate electrode GE. The interlayer insulating layer 215 may include an inorganic material, such as SiOₓ, SiNₓ, and/or SiON.

The source electrode SE and the drain electrode DE may be disposed above the interlayer insulating layer 215. In an embodiment, one of the source electrode SE and the drain electrode DE may be omitted and replaced with a conductized semiconductor layer ACT.

The gate electrode GE, the source electrode SE, and the drain electrode DE may include a conductive material. The gate electrode GE may include at least one of molybdenum (Mo), aluminum (Al), copper (Cu), and titanium (Ti) and may have a multilayered structure. For example, the gate electrode GE may be a single Mo layer. In an embodiment, the gate electrode GE may have a three-layer structure including an Mo layer, an Al layer, and an Mo layer. The source electrode SE and the drain electrode DE may each include at least one of Cu, Ti, and Al and may have a multilayered structure. For example, the source electrode SE and the drain electrode DE may each have a three-layer structure including a Ti layer, an Al layer, and a Ti layer.

A buffer layer 211 may be arranged between the thin-film transistor TFT and the substrate 100. The buffer layer 211 may include an inorganic material, such as SiOₓ, SiNₓ, and/or SiON. The buffer layer 211 may increase the flatness of an upper surface of the substrate 100 or may prevent or decrease the penetration of impurities to the semiconductor layer ACT of the thin-film transistor TFT from the substrate 100, etc.

A planarization insulating layer 217 may be disposed above the thin-film transistor TFT. The planarization insulating layer 217 may include an organic material, for example, an acrylic material, benzocyclobutene (BCB), hexamethyldisiloxane (HMDSO), or the like. FIG. 6 shows that the planarization insulating layer 217 is a single layer, but the disclosure is not limited thereto, and the planarization insulating layer 217 may have multiple layers.

The display element layer 220 may include display elements (for example, organic light-emitting diodes). For example, the display element layer 220 may include a pixel electrode 221, an emission layer 222, and an opposite electrode 223.

The pixel electrode 221 may be disposed above the planarization insulating layer 217. The pixel electrode 221 may be arranged for each pixel (P1, P2, and P3 of FIG. 5). Portions of the pixel electrode 221 that respectively correspond to neighboring pixels may be arranged apart from each other. The pixel electrode 221 may be a transmissive electrode, a semi-transmissive electrode, or a reflection electrode. In an embodiment, the pixel electrode 221 may include a reflective layer and an electrode layer. The reflective layer may include silver (Ag), magnesium (Mg), Al, platinum (Pt), palladium (Pd), gold (Au), nickel (Ni), neodymium (Nd), iridium (Ir), chromium (Cr), or an alloy thereof. The electrode layer may be formed on the reflective layer and may be transparent or translucent. The electrode layer may include at least one of indium tin oxide (ITO), indium zinc oxide (IZO), zinc oxide (ZnO), indium oxide (In₂O₃), indium gallium oxide (IGO), and aluminum zinc oxide (AZO). For example, the pixel electrode 221 may have a stack structure of ITO/Ag/ITO.

A pixel-defining layer 219 may be disposed above the pixel electrode 221. The pixel-defining layer 219 may have an opening through which the upper surface of each pixel electrode 221 is exposed. The opening of the pixel-defining layer 219 may define the emission area EA of the pixel. The pixel-defining layer 219 may cover edges of the pixel electrode 221 and increase a distance between the edges of the pixel electrode 221 and the opposite electrode 223, thereby preventing arcs, etc. from being generated on the edges of the pixel electrode 221. The pixel-defining layer 209 may include an organic insulating material, such as PI, polyamide, an acrylic resin, BCB, HMDSO, and a phenol resin, and may be formed through spin coating, etc. In another embodiment, the pixel-defining layer 219 may include an inorganic insulating material. In another embodiment, the pixel-defining layer 209 may have a multilayered structure including an inorganic insulating material and an organic insulating material.

In some embodiments, the pixel-defining layer 219 may include a light-shielding material and may be black. The light-shielding material may include carbon black, a carbon nanotube, a resin or paste including a black dye, metal particles such as Ni, Al, Mo, an alloy thereof, metal oxide particles (e.g., chromium oxide), metal nitride particles (e.g., chromium nitride), or the like.

The emission layer 222 may be disposed above the pixel electrode 221. The emission layer 222 may include an organic material including a fluorescent material or a phosphorescent material emitting red light, green light, or blue light. The organic material may be a low-molecular-weight organic material or a high-molecular-weight organic material. The emission layer 222 may be arranged to correspond to the pixel electrode 221.

A first common layer (not shown) and/or a second common layer (not shown) may be disposed under and above the emission layer 222. The first common layer may be disposed under the emission layer 222 and include, for example, a Hole Transport Layer (HTL), a Hole Injection Layer (HIL) or both an HTL and HIL. The second common layer may be disposed above the emission layer 222 and include an Electron Transport Layer (ETL) and/or an Electron Injection Layer (EIL). In embodiments, the second common layer may be omitted. Like the opposite electrode 223 described below, each of the first common layer and the second common layer may be integrally formed to entirely cover the substrate 100, for example, the display area of the substrate 100.

The opposite electrode 223 may be a cathode that is an electron injection electrode, and metal having a low work function, alloys, an electrically conductive compound, or a combination thereof may be used for the opposite electrode 223. The opposite electrode 223 may be a transmissive electrode, a semi-transmissive electrode, or a reflection electrode. The opposite electrode 223 may include lithium (Li), Ag, Mg, Al, Al—Li, calcium (Ca), Mg—In, Mg—Ag, ytterbium (Yb), Ag—Yb, ITO, IZO, or an alloy thereof. The opposite electrode 223 may have a single-layer structure including a single layer or a multilayered structure including layers.

A capping layer (not shown) may be further disposed above the opposite electrode 223. The capping layer may be configured to improve the external emission efficiency of an organic light-emitting diode, according to the principle of constructive interference. The capping layer may include a material having a refractive index greater than or equal to about 1.6 (at 589 nm). The thickness of the capping layer may be in a range of about 1 nm to about 200 nm. For example, the thickness of the capping layer may be in a range of about 5 nm to about 150 nm. For example, the thickness of the capping layer may be in a range of about 10 nm to 100 nm. The capping layer may include an organic capping layer including an organic material, an inorganic capping layer including an inorganic material, and a composite capping layer including an organic material and an inorganic material.

The encapsulation layer TFE may be disposed above the display element layer 220 and seal the display element of the display element layer 220. The encapsulation layer TFE may include at least one inorganic encapsulation layer and at least one organic encapsulation layer. At least one inorganic encapsulation layer may include an inorganic material such as aluminum oxide (Al₂O₃), titanium oxide (TiO₂), tantalum oxide (Ta₂O₅), zinc oxide (ZnO), SiO₂, SiNₓ, and SiON. At least one organic encapsulation layer may include a polymer-based material. The polymer-based material may include an acrylic resin, an epoxy-based resin, PI, polyethylene, and the like. In an embodiment, at least one organic encapsulation layer may include acrylate.

According to embodiments, the encapsulation layer TFE may include a first inorganic encapsulation layer 310, a second inorganic encapsulation layer 330, and an organic encapsulation layer 320. The first inorganic encapsulation layer 310 may cover the opposite electrode 223. The first inorganic encapsulation layer 310 may include an inorganic insulating material. The inorganic insulating material may include Al₂O₃, TiO₂, Ta₂O₅, hafnium oxide (HfO₂), ZnO, SiO₂, SiNₓ, SiON, or a combination thereof. The first inorganic encapsulation layer 310 may be formed through CVD.

The organic encapsulation layer 320 may be disposed on and cover the upper surface of the first inorganic encapsulation layer 310. The organic encapsulation layer 320 may include a polymer. The polymer may include an acrylic resin, an epoxy-based resin, PI, polyethylene, and the like. For example, the organic encapsulation 320 layer may include an acrylic resin including poly(methylmethacrylate) (PMMA) and/or polyacrylic resin. The organic encapsulation layer 320 may be formed by curing a monomer or applying a polymer. The organic encapsulation layer 320 may cover uneven portions of the display element layer 220, and thus, the upper surface of the organic encapsulation layer 320 may be flatter than the upper surface of the first inorganic encapsulation layer 310.

The second inorganic encapsulation layer 330 may be provided on the upper surface of the organic encapsulation layer 320. The second inorganic encapsulation layer 330 may include the inorganic insulating material that may be used to the first inorganic encapsulation layer 310. The second inorganic encapsulation layer 330 may be formed through CVD.

The touch sensor layer 350 may include a first inorganic insulating layer IL1, a first conductive layer CL1, a second inorganic insulating layer IL2, and a second conductive layer CL2. The first inorganic insulating layer IL1 may be provided on the second inorganic encapsulation layer 330. The first inorganic insulating layer IL1 may be a layer or layers. The first inorganic insulating layer IL1 may include an inorganic material or a composite material. For example, the first inorganic insulating layer IL1 may include an inorganic layer. For example, the first inorganic insulating layer IL1 may include at least one of AlO₃, TiO₂, SiO₂, SiON, zirconium oxide (ZrO₂), and HfO₂.

The second inorganic insulating layer IL2 may be provided on the first inorganic insulating layer IL1. The second inorganic insulating layer IL2 may be a layer or layers. The second inorganic insulating layer IL2 may include an inorganic material or a composite material. For example, the second inorganic insulating layer IL2 may include an inorganic layer that can be used for the first inorganic insulating layer IL1.

The first conductive layer CL1 may be provided on the upper surface of the first inorganic insulating layer IL1. The first conductive layer CL1 may be arranged between the first inorganic insulating layer IL1 and the second inorganic insulating layer IL2.

The second conductive layer CL2 may be arranged on the upper surface of the second inorganic insulating layer IL2. The second conductive layer CL2 may be electrically connected to the first conductive layer CL1 through a contact hole (not shown). The contact hole may be provided in the second inorganic insulating layer IL2.

The first conductive layer CL1 and the second conductive layer CL2 may correspond to sensing electrodes. The sensing electrode may not overlap the emission area EA and may overlap a non-emission area in a plan view. The first conductive layer CL1 and the second conductive layer CL2 may each have a mesh shape, in a plan view.

The first conductive layer CL1 and the second conductive layer CL2 may each have a single layer structure or a multilayered structure. The first conductive layer CL1 and the second conductive layer CL2 may each include a metal layer or a transparent conductive layer. The metal layer may include Mo, Ag, Ti, Cu, Al, and an alloy thereof. The transparent conductive layer may include transparent conductive oxide, such as ITO, IZO, ZnO, and/or ITZO. In another embodiment, the transparent conductive layer may include a conductive polymer, such as PEDOT, metal nanowires, and/or graphene.

The anti-reflection layer 400 may be disposed above the touch sensor layer 350.

The light control film 500 may be disposed above the anti-reflection layer 400. The light control film 500 may include the reflective wall structures 550 and the light-transmissive layer 530. The light-transmissive layer 530 may be arranged between the reflective wall structures 550. The first light emitted from the display element layer 220 may be externally discharged through the light-transmissive layer 530. The light-transmissive layer 530 may include a transmissive organic material. For example, the light-transmissive layer 530 may include an acrylic resin (e.g., PMMA, polyacrylic resin, etc.), ethyl hexyl acrylate, pentafluoropropyl acrylate, poly(ethylene glycol) dimethacrylate, or ethylene glycol dimethacrylate. The light-transmissive layer 530 may have a refractive index in a range of about 1.3 to about 1.7, but the range is not limited thereto.

The reflective wall structures 550 may be arranged apart from each other. Each reflective wall structure 550 may include reflective particles 551 and a base layer 559. The base layer 559 may include a transmissive organic material. The transmissive organic material may include, for example, an acrylic resin, but is not limited thereto. The base layer 559 and the light-transmissive layer 530 may include a same material or different materials. For example, the base layer 559 may have a refractive index in a range of about 1.3 to about 1.7. The refractive index of the base layer 559 and the refractive index of the light-transmissive layer 530 may be the same or similar. For example, the refractive index of the base layer 559 may be in a range of about 90% to about 110% of the refractive index of the light-transmissive layer 530. Accordingly, undesired reflection, refraction, or scattering of light may be prevented on the interface between the light-transmissive layer 530 and the base layer 559. As described below, the light penetrating the base layer 559 may be reflected from the reflective particles 551.

The reflective particles 551 may be provided in the base layer 559. For example, the reflective particles 551 may be dispersed in the base layer 559. The reflective particles 551 may have high reflectivity and reflect light in the visible band. For example, the reflective particles 551 may have high reflectivity with respect to light in a first wavelength band, light in a second wavelength band, and light in a third wavelength band. The reflective particles 551 may include a high-reflective material. For example, the high-reflective material may include a metal material, such as Al, Ag, and/or tin (Sn). In another embodiment, the high-reflective material may include metal oxide, such as TiO₂, but is not limited thereto. A diameter of each reflective particle 551 may be in a range of about 3 μm to about 10 μm, but is not limited thereto. As shown in FIG. 7, the second light emitted from the display element layer 220 may be reflected from the reflective particles 551.

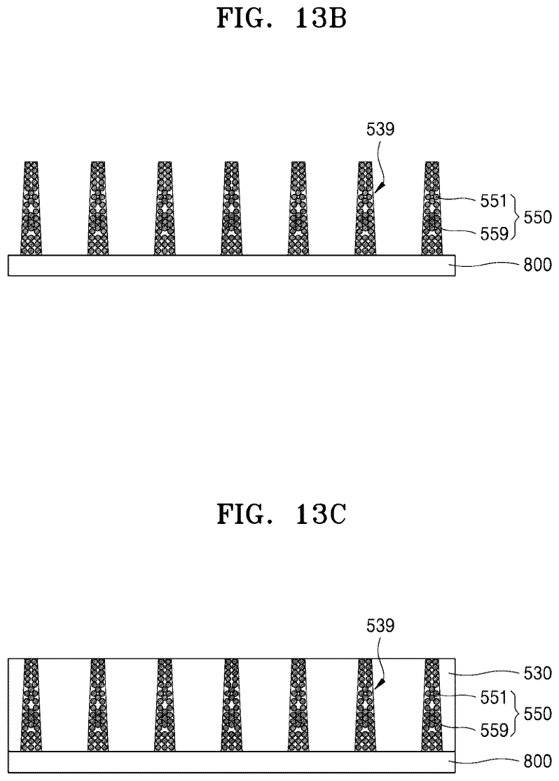

The reflective wall structure 550 may have a cross-section with a trapezoid shape or a shape similar to a trapezoid. The width W2 of the upper surface of each reflective wall structure 550 may be greater than the width W1 of the lower surface of the reflective wall structure 550. Each reflective wall structure 550 may have an aspect ratio of about 1:8 to about 1:12. An aspect ratio of a component may be a width of a lower surface of the component to a height of the component. A sidewall of each reflective wall structure 550 may be inclined with respect to the lower surface of the reflective wall structure 550. As shown in FIG. 7, for example, an angle θ between a lower surface and a sidewall of one of the reflective wall structures 550 may be an obtuse angle. The reflective particles 551 may be arranged in a direction parallel to the sidewalls of the reflective wall structures 550. The second light emitted from the display element layer 220 may be incident to the sidewalls of the reflective wall structures 550 at a certain angle. Because the angle 0 between the lower surface and the sidewall of the reflective wall structure 550 is an obtuse angle, most of the second light reflected from the reflective particles 551 may not be discharged towards the second organic layer 520, as indicated by an arrow of FIG. 7. For example, most of the second light reflected from the reflective particles 551 may not be discharged towards a front surface (FS1 of FIG. 12) of the display apparatus 1. The second light discharged towards the second organic layer 520 may be little or significantly small, compared to the second light that is blocked. Accordingly, the second light may be effectively blocked. The viewing angle restriction characteristics of the display apparatus 1 may be improved due to the light control film 500.

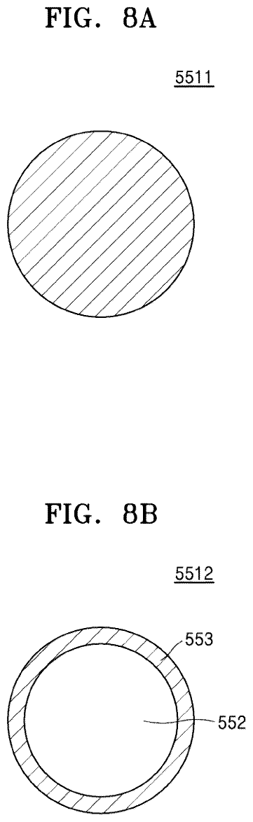

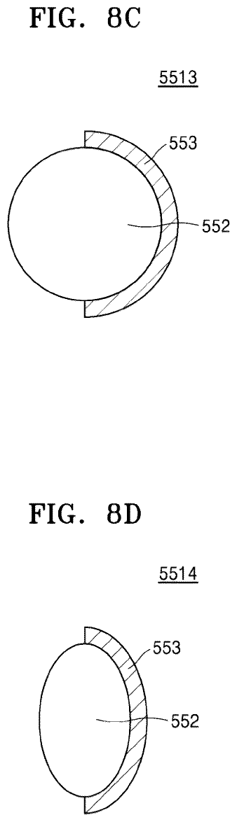

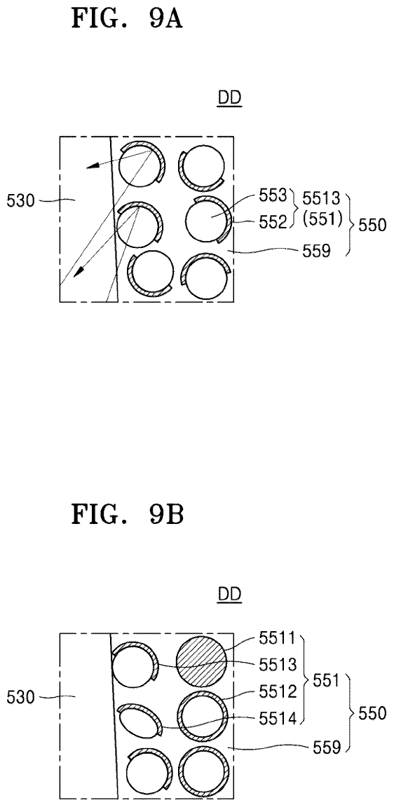

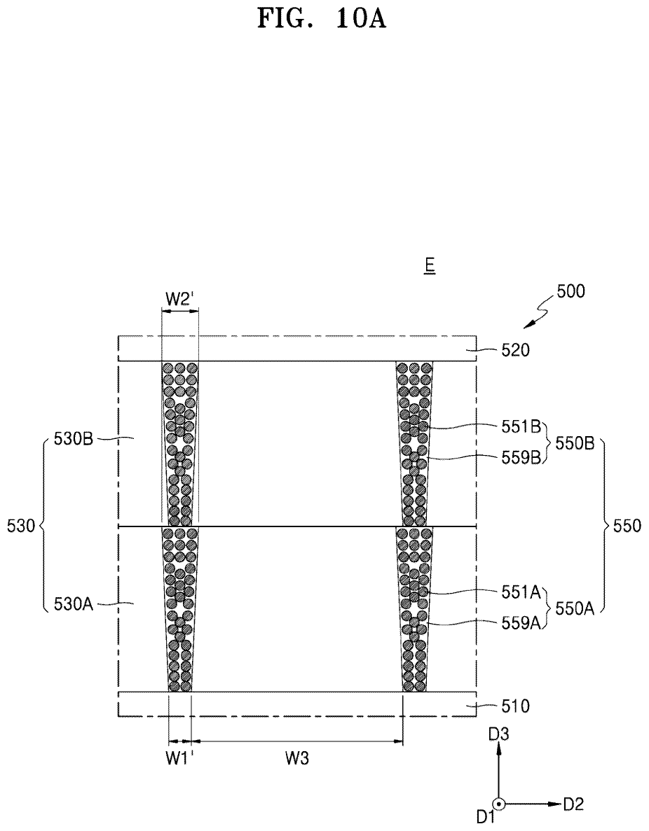

Types of the reflective particles 551 may vary. For example, the reflective particles 551 may include at least one of a first sub-reflective particle 5511 of FIG. 8A, a second sub-reflective particle 5512 of FIG. 8B, a third sub-reflective particle 5513 of FIG. 8C, and a fourth sub-reflective particle 5514 of FIG. 8D. Hereinafter, the first sub-reflective particle 5511 to the fourth sub-reflective particle 5514 are described.

FIG. 8A is a schematic diagram for explaining a first sub-reflective particle according to an embodiment.

Referring to FIG. 8A, the first sub-reflective particle 5511 may include the high-reflective material described above. The inside and outside of the first sub-reflective particle 5511 may include a same material. the first sub-reflective particle 5511 may not include a bead portion (552 of FIG. 8B) described below with reference to FIG. 8B.

FIG. 8B is a schematic diagram for explaining a second sub-reflective particle according to an embodiment.

Referring to FIG. 8B, the second sub-reflective particle 5512 may include a bead portion 552 and a reflection shell portion 553. The bead portion 552 may be transparent. A refractive index of the bead portion 552 and the refractive index of the base layer 559 of FIGS. 5 and 6 may be the same or similar. Accordingly, undesired reflection, refraction, or scattering of light may be prevented on the interface between the bead portion 552 and the base layer 559. The bead portion 552 may include a transmissive polymer. The bead portion 552 and the base layer 559 may include a same or similar material. The bead portion 552 may have a circular shape or an oval shape in a cross-sectional view.

The reflection shell portion 553 may be provided on and surround the bead portion 552. The reflection shell portion 553 may entirely cover the bead portion 552. Accordingly, the bead portion 552 may not be externally exposed by the reflection shell portion 553. The reflection shell portion 553 may include the high-reflective material described above. Light may be reflected from the reflection shell portion 553. The reflection shell portion 553 may be formed through printing, deposition, or etching.

FIG. 8C is a schematic diagram for explaining a third sub-reflective particle according to an embodiment.

Referring to FIG. 8C, the third sub-reflective particle 5513 may include a bead portion 552 and a reflection shell portion 553. The bead portion 552 and the reflection shell portion 553 may be similar to those described above with reference to FIG. 8B. For example, the bead portion 552 may have a circular cross-sectional shape. However, the reflection shell portion 553 may partially cover the bead portion 552. For example, the reflection shell portion 553 may cover a portion of the bead portion 552, and another portion of the bead portion 552 may be exposed by the reflection shell portion 553. The reflection shell portion 553 may have a hollow hemispherical shape, but the shape thereof is not limited thereto. Light (e.g., the second light) may be reflected from the reflection shell portion 553.

FIG. 8D is a schematic diagram for explaining a fourth sub-reflective particle according to an embodiment.

Referring to FIG. 8D, the third sub-reflective particle 5514 may include a bead portion 552 and a reflection shell portion 553. The bead portion 552 and the reflection shell portion 553 may be similar to those described above with reference to FIGS. 8B and 8C. For example, at least a portion of the bead portion 552 may be exposed to the outside, and the reflection shell portion 553 may partially cover the bead portion 552. The bead portion 552 may have an oval cross-sectional shape.

Types of the reflective particles 551 may include the first sub-reflective particle 5511, the second sub-reflective particle 5512, the third sub-reflective particle 5513, and the fourth sub-reflective particle 5514, but the disclosure is not limited thereto. In the specification, the description that reflective particles included in any two components are of different types may indicate that any one of the components includes any one of the first sub-reflective particle 5511, the second sub-reflective particle 5512, the third sub-reflective particle 5513, and the fourth sub-reflective particle 5514 and that the other component includes another one of the first sub-reflective particle 5511, the second sub-reflective particle 5512, the third sub-reflective particle 5513, and the fourth sub-reflective particle 5514. It is not excluded that any one of the components further includes another one of the first sub-reflective particle 5511, the second sub-reflective particle 5512, the third sub-reflective particle 5513, and the fourth sub-reflective particle 5514.

Referring back to FIG. 6, the light control film 500 may further include the first organic layer 510. The first organic layer 510 may be provided on the lower surfaces of the reflective wall structures 550 and the lower surface of the light-transmissive layer 530. The first organic layer 510 may include a transparent polymer. For example, the first organic layer 510 may include PC. In another embodiment, the first organic layer 510 may include PI, PET, poly(butylene terephthalate) (PBT), polyethylene naphthalene (PEN), PMMA, polystyrene (PS), polyvinylchloride (PVC), and/or any combination thereof.

The light control film 500 may further include the second organic layer 520. The second organic layer 520 may be provided on the upper surfaces of the reflective wall structures 550 and the upper surface of the light-transmissive layer 530. The second organic layer 520 may include the transparent polymer that may be used for the first organic layer 510. The second organic layer 520 and the first organic layer 510 may include a same material or different materials. In another embodiment, the light control film 500 may not include at least one of the second organic layer 520 and the first organic layer 510.

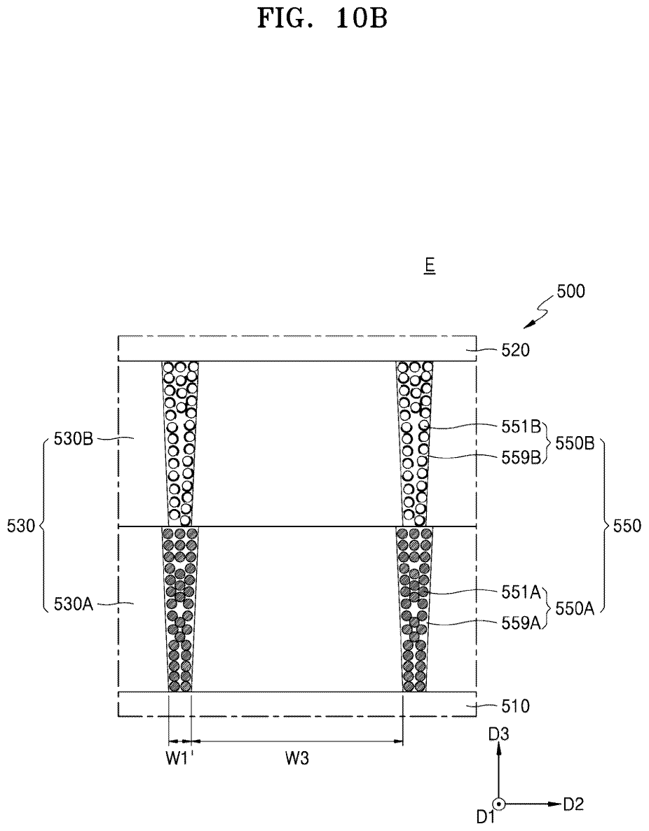

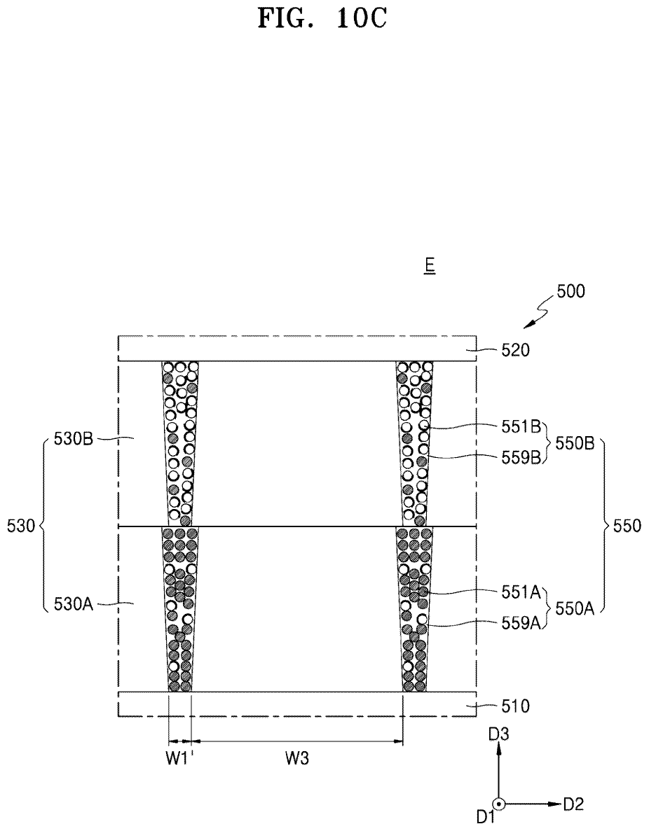

FIG. 9A is a schematic diagram for explaining a reflective wall structure according to another embodiment, and is an enlarged view of region DD of FIG. 7. Hereinafter, a single reflective wall structure is described.

Referring to FIG. 9A, the reflective wall structure 550 may include a base layer 559 and a reflective particle 551. The reflective particle 551 may include the third sub-reflective particle 5513 described above with reference to FIG. 8C. The second light emitted from the display element layer 220 may penetrate the bead portion 552 and may be reflected from the reflection shell portion 553. Because the reflective particle 551 includes the third sub-reflective particle 5513, the reflective wall structure 550 may effectively block the second light.

FIG. 9B is a schematic diagram for explaining a reflective wall structure according to another embodiment and shows enlarged region DD of FIG. 7.

Referring to FIG. 9B, the reflective particle 551 may include different types of sub-reflective particles. For example, the reflective particles 551 may include the first sub-reflective particle 5511, the second sub-reflective particle 5512, the third sub-reflective particle 5513, and the fourth sub-reflective particle 5514. In another embodiment, the reflective particle 551 may not include one of the first sub-reflective particle 5511, the second sub-reflective particle 5512, the third sub-reflective particle 5513, and the fourth sub-reflective particle 5514. Types of the reflective particles 551 included in the reflective wall structure 550 may vary.

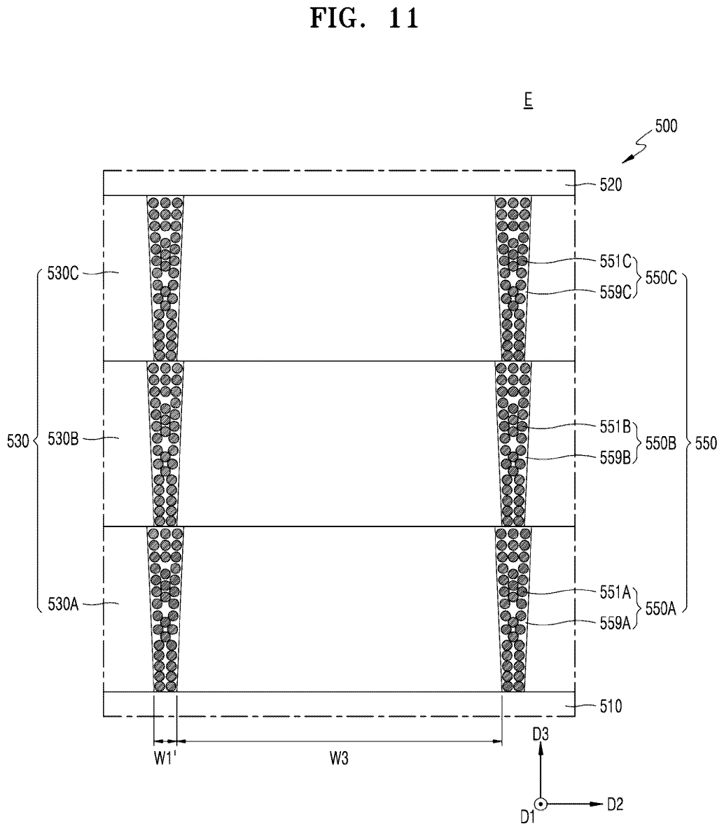

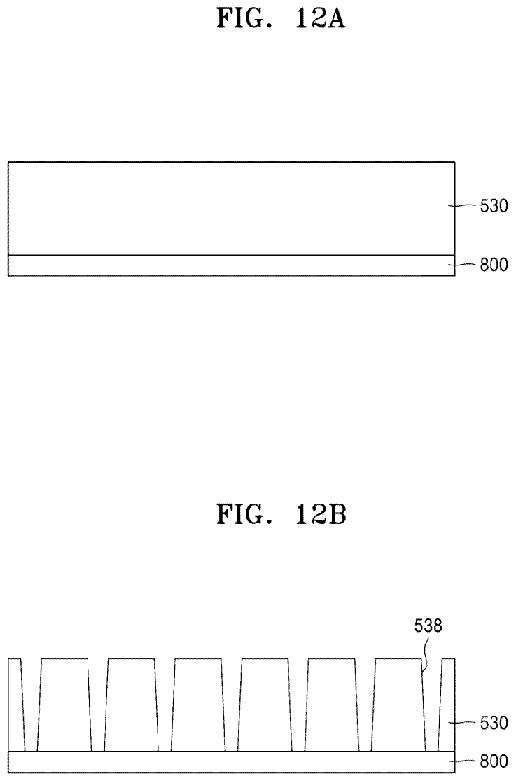

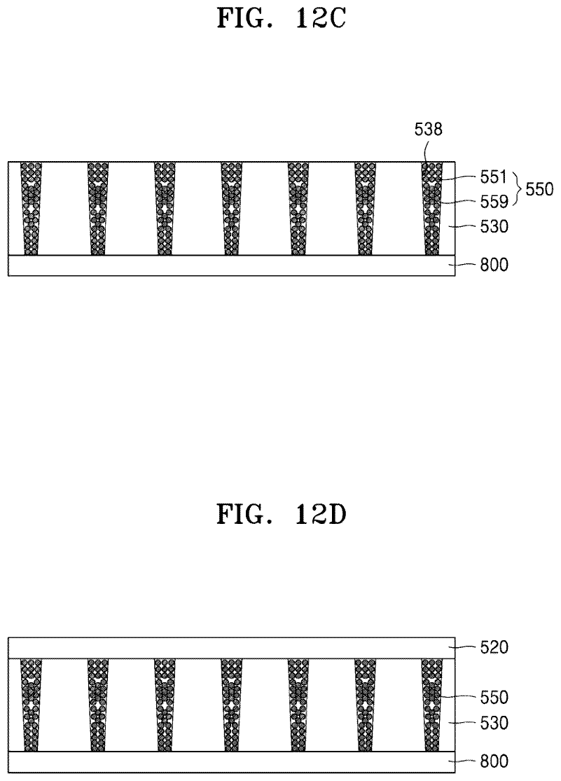

FIG. 10A is a schematic diagram for explaining a light control film according to an embodiment and corresponds to an enlarged view of region E of FIG. 6.

Referring to FIG. 10A, a light control film 500 may include a light-transmissive layer 530 and a reflective wall structure 550. The reflective wall structure 550 may further include a first organic layer 510 and a second organic layer 520.

The reflective wall structure 550 may include a first reflective wall structure 550A and a second reflective wall structure 550B. A width of a lower surface of the reflective wall structure 550 may correspond to a width W1′ of a lower surface of the first reflective wall structure 550A, and a width of an upper surface of the reflective wall structure 550 may correspond to a width W2′ of an upper surface of the second reflective wall structure 550B. The width W1′ of the lower surface of the first reflective wall structure 550A may be less than the width W2′ of the upper surface of the first reflective wall structure 550A. Accordingly, an angle between the lower surface and the sidewall of the first reflective wall structure 550A may be an obtuse angle. Accordingly, the first reflective wall structure 550A may effectively block the second light. An aspect ratio of the first reflective wall structure 550A may be in a range of about 1:8 to about 1:12. The first reflective wall structure 550A may include a first base layer 559A and a first reflective particle 551A. The first base layer 559A and the first reflective particle 551A may be substantially the same as the base layer 559 and the reflective particle 551 described above with reference to FIGS. 6 and 7. For example, the first reflective particle 551A may include at least one of the first sub-reflective particle 5511 of FIG. 8A, the second sub-reflective particle 5512 of FIG. 8B, the third sub-reflective particle 5513 of FIG. 8C, and the fourth sub-reflective particle 5514 of FIG. 8D.

The second reflective wall structure 550B may be disposed above the first reflective wall structure 550A. A width of a lower surface of the second reflective wall structure 550B may be less than the width W2′ of the upper surface of the first reflective wall structure 550A. Accordingly, a portion of the upper surface of the first reflective wall structure 550A may be exposed by the second reflective wall structure 550B. The width of the lower surface of the second reflective wall structure 550B may be less than the width of the upper surface of the second reflective wall structure 550B. An angle between the lower surface and the sidewall of the second reflective wall structure 550B may be an obtuse angle. The second light may be effectively blocked by the second reflective wall structure 550B. The width of the upper surface of the second reflective wall structure 550B may be greater than the width W1′ of the lower surface of the first reflective wall structure 550A. An aspect ratio of the second reflective wall structure 550B may be in a range of about 1:8 to about 1:12.

In general, it may be challenging to manufacture a reflective wall structure 550 with a great aspect ratio because of a limitation on the manufacturing processes of the reflective wall structure 550. According to an embodiment, because the reflective wall structure 550 includes the first reflective wall structure 550A and the second reflective wall structure 550B which are stacked, the reflective wall structure 550 may have a relatively great aspect ratio. For example, the reflective wall structure 550 may have an aspect ratio greater than or equal to at least 1:18. The aspect ratio of the reflective wall structure 550 according to an embodiment may be the width W1′ of the first reflective wall structure 550A to the sum of a height of the first reflective wall structure 550A and a height of the second reflective wall structure 550B. Because of the great aspect ratio of the reflective wall structure 550 according to an embodiment, the limitation on the width W1′ of the first reflective wall structure 550A may decrease. For example, the width W1′ of the first reflective wall structure 550A may be reduced. Accordingly, the first light blocked by the first reflective wall structure 550A may be reduced. The light control film 500 may have high transmittance with respect to the first light.

The second reflective wall structure 550B may include a second base layer 559B and a second reflective particle 551B. The second base layer 559B and the second reflective particle 551B may be substantially the same as the base layer 559 and the reflective particle 551 described above with reference to FIGS. 6 and 7. For example, the first reflective particle 551A may include at least one of the first sub-reflective particle 5511 of FIG. 8A, the second sub-reflective particle 5512 of FIG. 8B, the third sub-reflective particle 5513 of FIG. 8C, and the fourth sub-reflective particle 5514 of FIG. 8D.

The light-transmissive layer 530 may include a first light-transmissive layer 530A and a second light-transmissive layer 530B. The first light-transmissive layer 530A may be provided on the first organic layer 510 and cover the sidewall of the first reflective wall structure 550A. For example, the first reflective wall structure 550A may be provided in plural, and the first light-transmissive layer 530A may be arranged between the first reflective wall structures 550A. The first light-transmissive layer 530A may be the same as the light-transmissive layer 530 described above with reference to FIGS. 5 and 6. For example, the first light-transmissive layer 530A and the light-transmissive layer 530 described above with reference to FIG. 6 may include a same material and perform a same function.

According to the reduction in the width W1′ of the first reflective wall structure 550A, the width of the lower surface of the first light-transmissive layer 530A may increase. Accordingly, the transmittance of the light control film 500 with respect to the first light may be improved.

The second light-transmissive layer 530B may be disposed above the first light-transmissive layer 530A. The second light-transmissive layer 530B may further cover the upper surface of the first reflective wall structure 550A which is exposed. The second light-transmissive layer 530B may cover the sidewall of the second reflective wall structure 550B. For example, the second reflective wall structure 550B may be provided in plural, and the second light-transmissive layer 530B may be arranged between the second reflective wall structures 550B. The second light-transmissive layer 530B and the light-transmissive layer 530 described above with reference to FIG. 6 may include a same material and perform a same function. The second light-transmissive layer 530B and the first light-transmissive layer 530A may include a same material. A refractive index of the second light-transmissive layer 530B and the refractive index of the first light-transmissive layer 530A may be the same or similar. Accordingly, the first light may readily penetrate the first light-transmissive layer 530A and the second light-transmissive layer 530B. The interface between the first light-transmissive layer 530A and the second light-transmissive layer 530B may not be distinguishable, but the disclosure is not limited thereto.

FIG. 10B is a schematic diagram for explaining a light control film according to another embodiment and corresponds to a diagram showing enlarged region E of FIG. 7. FIG. 10C is a schematic diagram for explaining a light control film according to another embodiment and corresponds to a diagram showing enlarged region E of FIG. 7.

Referring to FIGS. 10B and 10C, the light control film 500 may include a first organic layer 510, a reflective wall structure 550, a light-transmissive layer 530, and a second organic layer 520.

The reflective wall structure 550 may include a first reflective wall structure 550A and a second reflective wall structure 550B. The first reflective wall structure 550A and the second reflective wall structure 550B may be substantially the same as those described above with reference to FIG. 10A.

As shown in FIG. 10B, the first reflective particle 551A and the second reflective particle 551B may be of a different type. For example, the first reflective particle 551A may include the first sub-reflective particle 5511 of FIG. 8A, while the second reflective particle 551B may include the third sub-reflective particle 5513 of FIG. 8C. In another embodiment, the first reflective particle 551A may include the second sub-reflective particle 5512. The types of the first reflective particle 551A and the second reflective particle 551B may vary.

Referring to FIG. 10C, the first reflective particle 551A and the second reflective particle 551B may a same type. For example, the first reflective particle 551A may include the first sub-reflective particle 5511 and the third sub-reflective particle 5513. The second reflective particle 551B may include the first sub-reflective particle 5511 and the third sub-reflective particle 5513. However, a ratio of the first sub-reflective particle 5511 in the second reflective wall structure 550B may be different from a ratio of the first sub-reflective particle 5511 in the first reflective wall structure 550A.

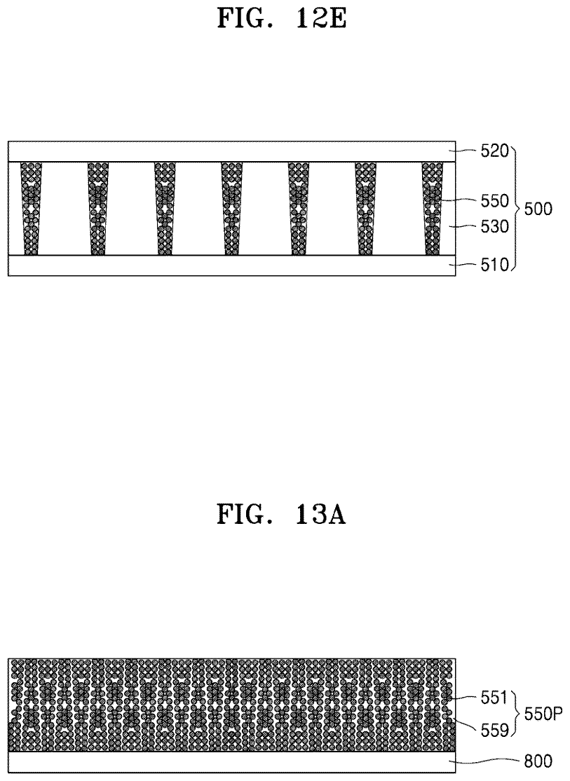

FIG. 11 is a schematic diagram for explaining a light control film according to another embodiment and corresponds to a diagram showing enlarged region E of FIG. 7.

Referring to FIG. 11, the light control film 500 may include a light-transmissive layer 530, a reflective wall structure 550, a first organic layer 510, and a second organic layer 520. The light-transmissive layer 530 may include a first light-transmissive layer 530A, a second light-transmissive layer 530B, and a third light-transmissive layer 530C.

The reflective wall structure 550 may include a first reflective wall structure 550A, a second reflective wall structure 550B, and a third reflective wall structure 550C. The first reflective wall structure 550A and the second reflective wall structure 550B may be substantially the same as those described above with reference to FIGS. 10A to 10C.

The third reflective wall structure 550C may be disposed on the upper surface of the second reflective wall structure 550B. A width of a lower surface of the third reflective wall structure 550C may be less than the width of the upper surface of the second reflective wall structure 550B. Accordingly, a portion of the upper surface of the second reflective wall structure 550B may be exposed by the third reflective wall structure 550C. The width of the lower surface of the third reflective wall structure 550C may be less than the width of the upper surface of the third reflective wall structure 550C. An angle between the lower surface and the sidewall of the third reflective wall structure 550C may be an obtuse angle. Accordingly, the second light may be further effectively blocked by the third reflective wall structure 550C. The aspect ratio of the third reflective wall structure 550C may be in a range of about 1:8 to about 1:12. The width of the upper surface of the third reflective wall structure 550C may be greater than the width W1′ of the lower surface of the first reflective wall structure 550A.

Because the reflective wall structure 550 includes the first reflective wall structure 550A, the second reflective wall structure 550B, and the third reflective wall structure 550C which are stacked, the reflective wall structure 550 may have a relatively great aspect ratio. For example, the reflective wall structure 550 may have an aspect ratio greater than or equal to at least 1:24. The aspect ratio of the reflective wall structure 550 according to an embodiment may be the width W1′ of the first reflective wall structure 550A to the sum of the height of the first reflective wall structure 550A, the height of the second reflective wall structure 550B, and the height of the third reflective wall structure 550C. According to embodiments, limitations on the width and the height of the reflective wall structure 550 may decrease. For example, the width W1′ of the first reflective wall structure 550A may decrease, and a width W3 of the first light-transmissive layer 530A may increase. Accordingly, the light control film 500 may have an improved transmittance with respect to the first light and effectively block the second light. The viewing angle restriction characteristics of the display apparatus 1 may be improved due to the light control film 500.

The third reflective wall structure 550C may include a third base layer 559C and a third reflective particle 551C. The third base layer 559C and the third reflective particle 551C may be substantially the same as the base layer 559 and the reflective particle 551 described above with reference to FIGS. 6 and 7. For example, the third reflective particle 551C may include at least one of the first sub-reflective particle 5511 of FIG. 8A, the second sub-reflective particle 5512 of FIG. 8B, the third sub-reflective particle 5513 of FIG. 8C, and the fourth sub-reflective particle 5514 of FIG. 8D. The type and content ratio of the third reflective particle 551C may vary.

The third light-transmissive layer 530C may be disposed above the second light-transmissive layer 530B. The third light-transmissive layer 530C may further cover the upper surface of the second reflective wall structure 550B which is exposed. The third light-transmissive layer 530C may cover the sidewall of the third reflective wall structure 550C. For example, the third reflective wall structure 550C may be provided in plural, and the third light-transmissive layer 530C may be arranged between the third reflective wall structures 550C. The third light-transmissive layer 530C and the light-transmissive layer 530 described above with reference to FIG. 6 may include a same material and perform a same function. The third light-transmissive layer 530C and the second light-transmissive layer 530B may include a same material. A refractive index of the third light-transmissive layer 530C and the refractive index of the second light-transmissive layer 530B may be the same or similar. Accordingly, the first light may readily penetrate the second light-transmissive layer 530B and the third light-transmissive layer 530C.

Each reflective wall structure 550 may include reflective wall structures with different numbers of stacked layers. For example, each reflective wall structure 550 may further include a fourth reflective wall structure on the third reflective wall structure 550C.

FIGS. 12A to 12E are schematic diagrams for explaining the manufacture of a light control film, according to embodiments.

Referring to FIG. 12A, a temporary substrate 800 may be prepared. The light-transmissive layer 530 may be formed on the temporary substrate 800. Forming the light-transmissive layer 530 may include applying a transmissive organic material onto the temporary substrate 800 and curing the applied transmissive organic material.

Referring to FIG. 12B, holes 538 may be formed in the light-transmissive layer 530, and thus, the upper surface of the temporary substrate 800 may be exposed. As the etching process is performed on the light-transmissive layer 530, the holes 538 may be formed. As a result of the etching process, widths of upper surfaces of the holes 538 may be greater than widths of lower surfaces thereof.

Referring to FIG. 12C, the reflective wall structures 550 may be formed in the holes 538. First, a base material and a preliminary material including the reflective particles 551 may be prepared. The preliminary material may be filled in the holes 538, and the preliminary material on the upper surface of the light-transmissive layer 530 may be removed. A curing process may be performed on the preliminary material to form the reflective wall structures 550. Through the curing process, the base material may form the base layer 559. Accordingly, each reflective wall structure 550 may include the base layer 559 and the reflective particles 551. The widths of the upper surfaces of the reflective wall structures 550 may be greater than the widths of the lower surfaces of the reflective wall structures 550.

Referring to FIG. 12D, the second organic layer 520 may be formed on the upper surfaces of the reflective wall structures 550 and the upper surface of the light-transmissive layer 530. The temporary substrate 800 may be removed so that the lower surfaces of the reflective wall structures 550 and the lower surface of the light-transmissive layer 530 may be exposed.

Referring to FIG. 12E, the first organic layer 510 may be formed on the lower surfaces of the reflective wall structures 550 and the lower surface of the light-transmissive layer 530. In another embodiment, the first organic layer 510 may be used as the temporary substrate 800, and the processes described with reference to FIGS. 12A to 12D may be performed on the first organic layer 510. A removal process of the temporary substrate 800 which is described with reference to FIG. 12D may be omitted. The manufacture of the light control film 500 may be completed according to the embodiments described so far.

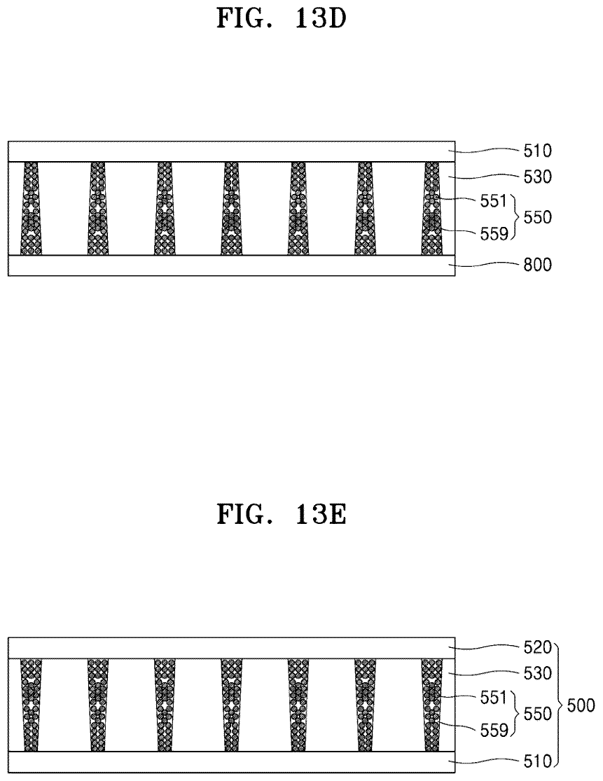

FIGS. 13A to 13E are schematic diagrams for explaining the manufacture of a light control film, according to embodiments. In the description of FIGS. 13A to 13E, lower and upper surfaces of a component are described based on corresponding drawings.

Referring to FIG. 13A, a preliminary reflection layer 550P may be formed on a temporary substrate 800. First, a base material and a preliminary material including the reflective particles 551 may be prepared. The preliminary material may be applied onto the temporary substrate 800. A curing process may be performed on the preliminary material to form the preliminary reflection layer 550P. Through the curing process, the base material may form the base layer 559. Accordingly, the preliminary reflection layer 550P may include the base layer 559 and the reflective particles 551.

Referring to FIG. 13B, the preliminary reflection layer 550P may be patterned, and thus, the reflective wall structures 550 may be formed. For example, patterning the preliminary reflection layer 550P may include performing an etching process on the preliminary reflection layer 550P. As a result of the etching process, the reflective wall structures 550 and grooves 539 may be formed. The grooves 539 may be formed between the reflective wall structures 550. As the result of the etching process, the widths of the upper surfaces of the reflective wall structures 550 may be less than the widths of the lower surfaces thereof. Each reflective wall structure 550 may include the base layer 559 and the reflective particles 551.

Referring to FIG. 13C, the light-transmissive layer 530 may be formed between the reflective wall structures 550 and on the temporary substrate 800. Forming the light-transmissive layer 530 may include filling a transmissive organic material in the grooves 539 and curing the transmissive organic material.

Referring to FIG. 13D, the first organic layer 510 may be formed on the upper surfaces of the reflective wall structures 550 and the upper surface of the light-transmissive layer 530. The temporary substrate 800 may be removed such that the lower surfaces of the reflective wall structures 550 and the lower surface of the light-transmissive layer 530 may be exposed. The second organic layer 520 may be formed on the lower surfaces of the reflective wall structures 550 and the lower surface of the light-transmissive layer 530. In another embodiment, the second organic layer 520 may be used as the temporary substrate 800, and the processes described with reference to FIGS. 13A to 13D may be performed on the second organic layer 520. A removal process of the temporary substrate 800 which is described with reference to FIG. 13D may be omitted.

Referring to FIG. 13E, a structure, which includes the first organic layer 510, the light-transmissive layer 530, the reflective wall structures 550, and the second organic layer 520, may be inverted so that the first organic layer 510 faces downwards. The upper surfaces of the reflective wall structures 550 of FIG. 13E may correspond to the lower surfaces of the reflective wall structures 550 of FIGS. 13B to 13E. The manufacture of the light control film 500 may be completed according to the embodiments described so far.

According to embodiments, a display apparatus may include a light control film, and the light control film may include reflective wall structures. Because of the reflective wall structures, a viewing angle of light emitted from a display element layer may be restricted and controlled. However, the scope of the disclosure is not limited by the effects.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
a display element layer on a substrate;
a cover window on the display element layer; and
a light control film between the display element layer and the cover window, wherein
the light control film comprises:
a reflective wall structure comprising a plurality of reflective particles; and
a light-transmissive layer covering a sidewall of reflective wall structure,
a width of a lower surface of the reflective wall structure is less than a width of an upper surface of the reflective wall structure, and
the lower surface of the reflective wall structure faces the display element layer.

2. The display apparatus of claim 1, wherein the reflective wall structure further comprises:
a first reflective wall structure; and
a second reflective wall structure provided on the first reflective wall structure.

3. The display apparatus of claim 2, wherein
a width of a lower surface of the first reflective wall structure is less than a width of an upper surface of the first reflective wall structure, and
a width of a lower surface of the second reflective wall structure is less than a width of an upper surface of the second reflective wall structure.

4. The display apparatus of claim 2, wherein the reflective wall structure further comprises a third reflective wall structure provided on the second reflective wall structure.

5. The display apparatus of claim 1, wherein the
reflective wall structure further comprises a base layer,
the plurality of reflective particles are provided in the base layer, and
a refractive index of the base layer is in a range of about 90% to about 110% of a refractive index of the light-transmissive layer.

6. The display apparatus of claim 1, wherein each of the plurality of reflective particles comprises:
a bead portion; and
a reflection shell portion covering the bead portion.

7. The display apparatus of claim 6, wherein the bead portion is completely covered by the reflection shell portion.

8. The display apparatus of claim 6, wherein
the reflection shell portion covers a portion of the bead portion, and
another portion of the bead portion is exposed by the reflection shell portion.

9. The display apparatus of claim 8, wherein the bead portion has a circular cross-sectional shape.

10. The display apparatus of claim 8, wherein the bead portion has an oval cross-sectional shape.

11. The display apparatus of claim 6, wherein
the bead portion comprises a transmissive polymer, and
the reflection shell portion comprises a metal or a metal oxide.

12. The display apparatus of claim 1, wherein
the light control film further comprises:
a first organic layer on the lower surface of the reflective wall structure and a lower surface of the light-transmissive layer; and
a second organic layer on the upper surface of the reflective wall structure and an upper surface of the light-transmissive layer,
the first organic layer comprises a first transparent polymer, and
the second organic layer comprises a second transparent polymer.

13. The display apparatus of claim 1, further comprising:
an encapsulation layer between the display element layer and the light control film; and
an anti-reflection layer between the encapsulation layer and the light control film.

14. The display apparatus of claim 1, further comprising:
a lower adhesive layer between the display element layer and the light control film; and
an upper adhesive layer between the light control film and the cover window.

15. A display apparatus comprising:
a display element layer on a substrate;
a light control film on the display element layer; and
a cover window on the light control film, wherein
the light control film comprises:
a plurality of reflective wall structures spaced apart from each other; and
a light-transmissive layer between the plurality of reflective wall structures, and
each of the plurality of reflective wall structures comprises:
a first reflective wall structure comprising a first base layer and a plurality of first reflective particles; and
a second reflective wall structure provided on an upper surface of the first reflective wall structure and comprising a second base layer and a plurality of second reflective particles.

16. The display apparatus of claim 15, wherein
an angle between a lower surface and a sidewall of the first reflective wall structure is an obtuse angle, and
an angle between a lower surface and a sidewall of the second reflective wall structure is an obtuse angle.

17. The display apparatus of claim 16, wherein a width of the lower surface of the second reflective wall structure is less than a width of the upper surface of the first reflective wall structure.

18. The display apparatus of claim 15, wherein the light-transmissive layer comprises:
a first light-transmissive layer covering a sidewall of the first reflective wall structure; and
a second light-transmissive layer disposed above the first light-transmissive layer and covering a sidewall of the second reflective wall structure.

19. The display apparatus of claim 18, wherein the second light-transmissive layer covers a portion of the upper surface of the first reflective wall structure.

20. The display apparatus of claim 18, wherein the second light-transmissive layer and the first light-transmissive layer comprise a same material.
